(19) United States
(12) Patent Application Publication
(10) Pub. No.: US 2006/0076686 A1
(43) Pub. Date: Apr. 13, 2006

(54) Method for manufacturing an electronic module, and an electronic module

(76) Inventors: Risto Tuominen, Helsinki (FI); Petteri Palm, Helsinki (FI)

Correspondence Address: BIRCH STEWART KOLASCH & BIRCH, PO BOX 747, FALLS CHURCH, VA, 22040-0747, US

(21) Appl. No.: 10/546,920

(22) PCT Filed: Feb. 25, 2004
(86) PCT No.: PCT/FI04/00102

§ 371 Date: Aug. 25, 2005

(30) Foreign Application Priority Data
Feb. 26, 2003 (FI) 20030293

(51) Int. Cl. H01L 23/48

(52) U.S. Cl. 257/773

(57) ABSTRACT

This publication discloses an electronic module and a method for manufacturing an electronic module, in which a component (6) is attached to the surface of a conductive layer and electrical and electrical contacts are formed between the contact zones of the component (6) and the conductive layer. After this, an insulating-material layer (1), which surrounds the component (6) attached to the conductive layer, is formed on, or attached to the surface of the conductive layer. After this, conductive patterns (14) are formed from the conductive layer, to which the component (6) is attached.

The present invention relates to an electronic module and a method for manufacturing the electronic module.

In particular, the invention relates to an electronic module, which includes one or more components embedded in an installation base. The electronic module can be a module like a circuit board, which includes several components, which are connected to each other electrically, through conducting structures manufactured in the module. The components can be passive components, microcircuits, semiconductor components, or other similar components. Components that are typically connected to a circuit board form one group of components. Another important group of components are components that are typically packaged for connection to a circuit board. The electronic modules to which the invention relates can, of course, also include other types of components.

The installation base can be of a type similar to the bases that are generally used in the electronics industry as installation bases for electrical components. The task of the base is to provide components with a mechanical attachment base and the necessary electrical connections to both components that are on the base and those that are outside the base. The installation base can be a circuit board, in which case the construction and method to which the invention relates are closely related to the manufacturing technology of circuit boards. The installation base may also be some other base, for example, a base used in the packaging of a component or components, or a base for an entire functional module.

The manufacturing techniques used for circuit boards differ from those used for microcircuits in, among other things, the fact that the installation base in microcircuit manufacturing techniques, i.e. the substrate, is of a semiconductor material, whereas the base material of an installation base for circuit boards is some form of insulating material. The manufacturing techniques for microcircuits are also typically considerably more expensive that the manufacturing techniques for circuit boards.

The constructions and manufacturing techniques for the cases and packages of components, and particularly semiconductor components differ from the construction and manufacture of circuit boards, in that component packaging is primarily intended to form a casing around the component, which will protect the component mechanically and facilitate the handling of the component. On the surface of the component, there are connector parts, typically protrusions, which allow the packaged component to be easily set in the correct position on the circuit board and the desired connections to be made to it. In addition, inside the component case, there are conductors, which connect the connector parts outside the case to connection zones on the surface of the actual component, and through which the component can be connected as desired to its surroundings.

However, component cases manufactured using conventional technology demand a considerable amount of space. As electronic devices have grown smaller, there has been a trend to eliminate component cases, which take up space, are not essential, and create unnecessary costs. Various constructions and methods have been developed to solve this problem.

One known solution is flip-chip (FC) technology, in which non-packaged semiconductor components are installed and connected directly to the surface of the circuit board. However, flip-chip technology has many weaknesses and difficulties. For example, the reliability of the connections can be a problem, especially in applications, in which mechanical stresses arise between the circuit board and the semiconductor component. In an attempts to avoid mechanical stresses, a suitable elastic underfill, which equalizes mechanical stresses, is added between the semiconductor component and the circuit board. This procedural stage slows down the manufacturing process and increases costs. Even the thermal expansion caused by the normal operation of a device may cause mechanical stresses large enough to compromise the long-term reliability of an FC structure.

U.S. Pat. No. 4,246,595 discloses one solution, in which recesses are formed in the installation base for the components. The bottoms of the recesses are bordered by an insulation layer, in which holes are made for the connections of the component. After this, the components are embedded in the recesses with their connection zones facing the bottom of the recess, electrical contacts being formed to the components through the holes in the insulation layer. In such a method, problems can arise, for instance, when aligning the feed-throughs with the contact zones of the component. This is because the feed-throughs must be aligned relative to components lying under the insulation layer. In other ways too, the method does not correspond to the technology used nowadays (the patent dates from 1981).

JP application publication 2001-53 447 discloses a second solution, in which a recess is made for the component in the installation base. The component is placed in the recess, with the component's contact zones facing towards the surface of the installation base. Next, an insulation layer is made on the surface of the installation base and over the component. Contact openings for the component are made in the insulation layer and electrical contacts are made to the component, through the contact openings. In this method too, the alignment of the feed-throughs with the contact zones of the component can cause problems, as the alignment must be made relative to a component lying under the insulation layer. In the method, considerable accuracy is demanded in manufacturing the recess and setting the component in the recess, so that the component will be correctly positioned, to ensure the success of the feed-throughs, relative to the width and thickness of the installation board.

In general too, the connection of components through feed-throughs made in the insulation layer creates a challenge to techniques, in which an attempt is made to embed components inside a circuit board or other installation base. Problems can arise, for example, due to the alignment precision, the stress created on the surface of the component by the manufacture of the hole, and by the covering of the edge areas of the feed-through by conductive material. Even a partial reduction of the problems relating to feed-throughs would be beneficial to the low-cost manufacture of reliable electronic modules that include unpackaged components embedded in an installation base. On the other hand, embedding a component inside an installation base will allow the construction to better withstand mechanical stress, which has been a problem in flip-chip technology.

The invention is intended to create a method, with the aid of which unpackaged components, such as semiconductor components and particularly microcircuits, can be attached and connected reliably and economically to their installation base.

The invention is based on the component being attached to the surface of a conductive layer and electrical contacts being formed between the conductive layer and the contact zones of the component. An ultrasonic or thermo-compression methods, which are capable of forming metallurgical joints, are used to attach the components to the surface of the conductive layer. After this, an insulating-material layer, which surrounds the component attached to the conductive layer, is formed on, or attached to the surface of the conductive layer. After this, conductive patterns are formed from the conductive layer, to which the component is attached.

More specifically, the method according to the invention is characterized by what is stated in claim 1.

With the method according to the invention, it is possible to manufacture numerous different electronics module embodiments. One such electronic module embodiment is characterized by what is stated in claim 20. The characterizing features of another possible electronic module embodiment are, in turn, defined in claim 21. It is also possible to manufacture differing electronics modules with the aid of the method.

Considerable advantages are gained with the aid of the invention. This because it is possible, with the aid of the invention, to manufacture reliable and economical electronic modules, which include unpackaged components embedded in an installation base.

Because the components can be embedded inside the installation base, in preferred embodiments it is possible to achieve a reliable and mechanically durable construction.

With the aid of the invention, it is also possible to reduce the number of the problems that appear in the prior art, which are caused by the feed-throughs relating to connecting the components. This is because the invention has embodiments, in which there is no need at all to make feed-throughs, the components being instead connected, already in the installation stage, to the conductor membrane, from which the conductors leading to the components of the electronic module are made.

In the embodiments, an installation base, which can be a circuit board, is manufactured around the components attached to the conductive layer. Thus the components, of which there may be one or several, become embedded and connected as desired to the base construction being manufactured.

In the embodiments of the invention, it is thus possible to manufacture a circuit board, inside which components are embedded. The invention also has embodiments, with the aid of which a small and reliable component package can be manufactured around a component, as part of the circuit board. In such embodiments, the manufacturing process is simpler and cheaper that manufacturing methods in which separate cased components are installed and connected to the surface of the circuit board. The manufacturing method can also be applied to use the method to manufacture Reel-to-Reel products. Thin and cheap circuit-board products containing components can be made by using the methods according to the preferred embodiments.

The invention also permits many other preferred embodiments, which can be used to obtain significant additional advantages. With the aid of such embodiments, a component's packaging stage, the circuit board's manufacturing stage, and the assembly and connecting stage of the components, for example, can be combined to form a single totality. The combination of the separate process stages brings significant logistical advantages and permits the manufacture of small and reliable electronic modules. A further additional advantage is that such an electronic-module manufacturing method can mostly utilize known circuit-board manufacturing and assembly technologies.

The composite process according to the embodiment referred to above is, as a totality, simpler that manufacturing a circuit board and attaching a component to the circuit board using, for example, the flip-chip technique. By using such preferred embodiments, the following advantages are obtained, compared to other manufacturing methods:

Soldering is not needed in the connections of the components, instead an electrical connection between the connection zones on the surface of the component and the metal membrane of the installation base is created, for example, by ultrasonic welding, thermo-compression, or some other such method, in which the temperatures required to achieve electrical connections, though high, are of short duration and local, and in which high temperatures are not required over a wide area. This means that the connection of a component does not need metal being maintained molten for a long time with its associated high temperature. Thus, the construction is made more reliable than soldered connections. Particularly in small connections, the brittleness of the metal alloys create large problems. In a solderless solution according to a preferred embodiment, it is possible to achieve clearly smaller constructions than in soldered solutions. The manufacturing method can even be designed so that, during the connection process of a component, heat is brought only to the area of the connection, so that the areas most strongly heated are the connection zone of the component and the area to which the component is connected. Elsewhere in the structure the temperature remains low. This gives greater freedom of choice when selecting the materials of the installation base and the components. If ultrasonic welding is used as the connection method, higher temperatures may only be required to harden the fillers used. Polymer membranes, which are hardened other than through the effect of heat, for example, chemically or with the aid of electromagnetic radiation, such as UV light, can also be used in the method. In such a preferred embodiment of the invention, the temperature of the installation base and components can be kept very low during the entire process, for example, at less than 100° C.

As smaller structures can be manufactured using the method, the components can be placed closer together. Thus, the conductors between the components also become shorter and the characteristics of the electronic circuits improve. For example, losses, interferences, and transit-time delays can be significantly reduced.

The method permits a lead-free manufacturing process, which is environmentally friendly.

When using a solderless manufacturing process, fewer undesirable intermetallics also arise, thus improving the long-term reliability of the construction.

The method also permits three-dimensional structures to be manufactured, as the installation bases and the components embedded in them can be stacked on top of each other.

The invention also permits other preferred embodiments. For instance, flexible circuit boards can be used in connection with the invention. Further, in embodiments, in which the temperature of the installation base can be kept low during the entire process, organic manufacturing materials can be used comprehensively.

With the aid of embodiments, it is also possible to manufacture extremely thin structures, in which, despite the thinness of the structure, the components are entirely protected inside their installation base, such as a circuit board.

In embodiments, in which the components are located entirely inside the installation base, the connections between the circuit board and the components will be mechanically durable and reliable.

The embodiments also permit the design of electronic-module manufacturing processes requiring relatively few process stages. Embodiments with fewer process stages correspondingly also require fewer process devices and various manufacturing methods. With the aid of such embodiments, it is also possible in many cases to cut manufacturing costs compared to more complicated processes.

The number of conductive-pattern layers of the electronic module can also be chosen according to the embodiment. For example, there can be one or two conductive-pattern layers. Additional conductive-pattern layers can be manufactured on top of these, in the manner known in the circuit-board industry. A total module can thus incorporate, for example, three, four, or five conductive-pattern layers. The very simplest embodiments have only one conductive-pattern layer and indeed one conductor layer. In some embodiments, each of the conductor layers contained in the electronic module can be exploited when forming conductive patterns.

In embodiments, in which the conductor layer connected to a component is patterned only after the connection of the component, the conductor layer can include conductor patterns even at the location of the component. A corresponding advantage can also be achieved in embodiments, in which the electronic module is equipped with a second conductive-pattern layer, which is located on the opposite surface of the base material of the module (on the opposite surface of the insulation material layer relative to the conductive-pattern layer connected to the component). The second conductor layer can thus also include conductive patterns at the location of the component. The placing of conductive patterns in the conductor layers at the location of the component will permit a more efficient use of space in the module and a denser structure.

In the following, the invention is examined with the aid of examples and with reference to the accompanying drawings.

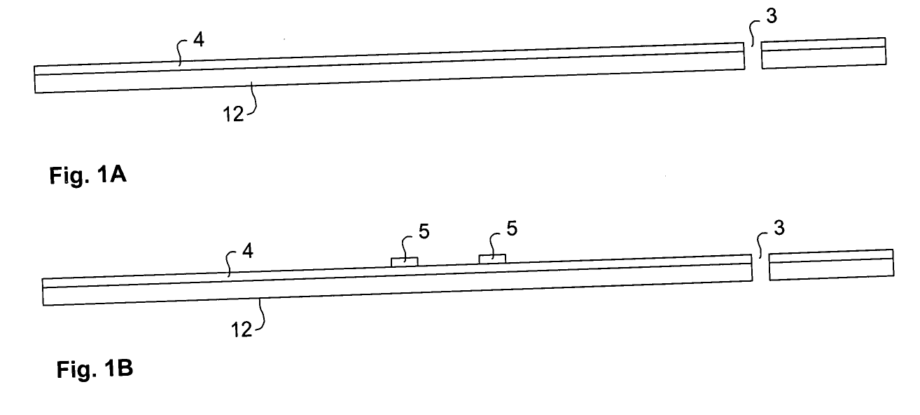

FIGS. 1-8 show a series of cross-sections of some examples of manufacturing methods according to the invention and schematic cross-sectional diagrams of some electronic modules according to the invention.

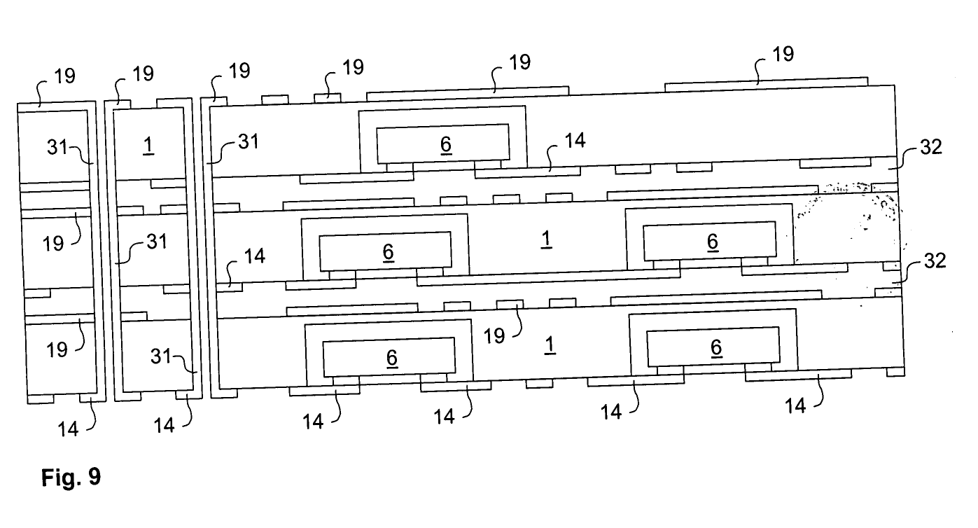

FIG. 9 shows a cross-sectional view of an electronic module according to the invention, which includes several installation bases on top of each other.

In the methods of the examples, manufacturing starts from a conductive layer 4, which can be, for example, a metal layer. One suitable manufacturing material for the conductive layer 4 is copper film (Cu). If the conductive film 4 selected for the process is very thin, or the conductive film is not mechanically durable for other reasons, it is recommended that the conductive film 4 be supported with the aid of a support layer 12. This procedure can be used, for example, in such a way that the process is started from the manufacture of the support layer 12. This support layer 12 can, for example, an electrically conductive material, such as aluminium (Al), steel, or copper, or an insulating material, such as a polymer. An unpatterned conductive layer 4 can be made on the second surface of the support layer 4, for example, by using some manufacturing method well known in the circuit-board industry. The conductive layer can be manufactured, for example, by laminating a copper film (Cu) on the surface of the support layer 12. Alternatively, it is possible to proceed by making the support layer 12 on the surface of the conductive layer 4.

The conductive layer 4 can also be surfaced with a metal film, or with some other film including several layers, or several materials. In some embodiments, it is possible to use, for example, a copper film, which is surfaced with a tin or gold layer. In these embodiments, the surfacing typically comes on the insulating-material-layer 1 side. It is also possible to proceed in such a way that the metal film 4 including a surfacing only in the area of the installation of the components 6.

Later in the process, conductive patterns are made from the conductive layer 4. The conductive patterns must then be aligned relative to the components 6. The alignment is most easily performed with the aid of suitable alignment marks, at least some of which can be made already in this stage of the process. Several different methods are available for creating the actual alignment marks. One possible method is to make small through-holes 3 in the conductive layer 4, in the vicinity of the installation areas of the components 6. The same through-holes 3 can also be used to align the components 6 and the insulating-material layer 1. There should preferably be at least two through-holes 3, for the alignment to be carried out accurately.

The connection zones or contact protrusions 7 on the surface of the components 6 are connected to the conductive layer 4, in order to form an electrical contact between the components and the conductive layer 4. The connection can be made using, for example, an ultrasonic or thermo-compression method.

The ultrasonic method then refers to a method, in which two pieces containing metal are pressed against each other while vibration energy at an ultrasound frequency is brought to the area of the joint. Due to the effect of the ultrasound and the pressure created between the surfaces to be joined, the pieces to be joined are bonded metallurgically. Methods and equipment for ultrasonic bonding are commercially available. Ultrasonic bonding has the advantage that a high temperature is not required to form a bond.

The term thermo-compression method refers in turn to a method, in which two pieces containing metal are pressed against each other while thermal energy is brought to the area of the joint. The effect of the thermal energy and the pressure created between the surfaces to be joined cause the pieces to be joined to be bonded metallurgically. Methods and equipment for thermo-compression bonding are also commercially available.

The terms metal layer, metal film, metal contact bump, metal contact zone, and in general a metal item, refer to the fact that the manufacturing material of the item contains enough of at least one metal for the item to form a metallurgical bond with another item. The item can naturally also include several metals as layers, accumulations, zones, or metal alloys. Possible metals include particularly copper, aluminium, gold, and tin.

When attaching the components 6, the components 6 can be aligned to their planned positions with the aid of alignment holes 3, or other alignment marks. Alternatively, it is possible to proceed by first attaching the components 6 to the conductive layer 4 positioned relative to each other, and after this making the alignment marks aligned relative to the components 6.

In some embodiments, contact bumps 5, to which the connection zones or contact protrusions 7 of the components 6 are connected, are made on top of the conductive film 4. In such a method, the contact bumps 5 can also be used to align the components 6 during the components' installation stage. The components 6 can, of course, be aligned with the aid of other alignment marks, for example, the alignment holes 3, if such are made in the process being used. The contact bumps 5 and the alignment holes 3 are then made aligned relative to each other. In embodiments using contact bumps 5, the procedure can otherwise correspond to embodiments in which contact bumps 5 are not used. The use of contact bumps 5 is justified, for example, if the material of the components' 6 contact zones or contact protrusions 7 is not directly suitable for connection to the selected material of the conducting layer 4. In that case, the material of the contact bumps 5 is selected to permit a bond using the bumps 5 to be created. In such embodiments, the contact bumps 5 are thus intended to match two different conductor materials to each other. For this purpose, the contact bump 5 can also be manufactured as a layered structure, containing two or more layers of differing materials.

After the connection of the components 6, the space remaining between the components 6 and the conducting layer 4 is filled with a suitable filler 8. In the examples of the figures, the filler is also spread around and on top of the component 6. The filler 8 is usually come polymer filler. With the aid of the filler 8, the mechanical connection between the component 6 and the conductive layer 4 can be reinforced, so that a mechanically more durable construction is achieved. The filler material 8 also supports the conductive patterns 14 to be formed later from the conducting layer 4 and to protect the components and the bond between the component 6 and the conducting layer 4 during the formation of the conductive patterns 14. In principle, the securing of the component 6 is not, however, an essential operation, especially in embodiments, in which mechanical durability or a long life are not demanded of the structure. The attachment of the components 6 can be performed immediately after connection and before the manufacture of the insulating-material layer 1. Attachment can quite as well also be performed after the manufacture of the insulating-material layer 1, in which case the through-holes made in the insulating-material layer 1 can be filled with some fuller 8. It is also possible to fill the space remaining between the components 6 and the conductive layer 4 with the material of the insulating-material layer 1, in which case the substance forming the insulating-material layer 1 will penetrate under the components 6, in connection with the manufacture of the insulating-material layer 1. The method can also be modified in such a way that the filler 8 is spread on the surface of the component 6 and/or of the conductive layer 4, prior to the attachment of the component 6. In such an embodiment, an electrical connection is thus formed through the filler layer 8, so that the filler 8 is displaced from between the metal parts being connected.

A suitable insulating-materia layer 1 is selected as the base material of the electronic module, for example, the circuit board. Using a suitable method, recesses, or through-holes are made in the insulating-material layer 1, according to the size and mutual positions of the components 6 to be attached to the conductive layer 4. In embodiments in which a filler 8 is used, space is left in the recesses or through-holes for the filler 8 too. The use of the recesses or through-holes that are larger than the components 6 is justified in other ways too, because the alignment of the conductive layer 4 with the insulating-material layer 1 is then not so critical and the danger of components 6 becoming detached also diminishes. If an insulating-material layer 1, in which through-holes are made for the components 6, is used in the process, certain advantages can be achieved by using, in addition, a separate insulating-material layer 11, in which holes are not made. Such an insulating-material layer 11 can be located on top of the insulating-material layer 1 to cover the through-holes made for the components.

If it is desired to make a second conductive layer in the electronic module, this can be made, for example, on the surface of the insulating-material layer 1. In embodiments, in which a second conductive layer 11 is used, the conductive layer can be made on the surface of this second conducive layer 11. If desired, conductive patterns 19 can be made from a second conductive layer 9. The conductive layer 9 can be made, for example, in a corresponding manner to the conductive film 4. The manufacture of a second conductive film 9 is not, however, necessary in simple embodiments and when manufacturing simple electronic modules. A second conductive film 9 can, however, be exploited in many ways, such as additional space for conductive patterns and to protect the components 6 and the entire module against electromagnetic radiation (EMC shielding). With the aid of a second conductive film 9 the structure can be reinforced and warping of the installation base, for example, can be reduced.

The manufacturing processes according to the examples can be implemented using manufacturing methods, which are generally known to those versed in the art of manufacturing circuit boards.

In the following, the stages of the method shown in FIGS. 1-8 are examined in greater detail.

Stage A (FIGS. 1A and 1B):

In stage A, a suitable conductive layer 4 is selected as the initial material of the process. A layered sheet, in which the conductive layer 4 is located on the surface of a support base 12, can also be selected as the initial material. The layered sheet can be manufactured, for example, in such a way that a suitable support base 12 is taken for processing, and a suitable conductive film for forming the conductive layer 4 is attached to the surface of this support base 12.

The support base 12 can be made of, for example, an electrically conductive material, such as aluminium (Al), or an insulating material, such as polymer. The conductive layer 4 can be formed, for example, by attaching a thin metal film to the second surface of the support base 12, for example, by laminating it from copper (Cu). The metal film can be attached to the support base, for example, using an adhesive layer, which is spread on the surface of the support base 12 or metal film prior to the lamination of the metal layer. At this stage, there need not be any patterns in the metal film. In the example of FIG. 1, holes 3 are made penetrating the support base 12 and the conductive layer 4, for alignment during the installation and connection of the components 6. Two through-holes 3, for example, can be manufactured for each component 6 to be installed. The holes 3 can be made using some suitable method, for example, mechanically by milling, impact, drilling, or with the aid of a laser. However, it is not essential to make through-holes 3, instead some other suitable alignment markings can be used to align the components. In the embodiment shown in FIG. 1, the through-holes 3 used to align the components extend through both the support base 12 and the conductive film 4. This has the advantage that the same alignment marks (through-holes 3) can be used for aligning on both sides of the installation base.

FIG. 1B shows an alternative embodiment, in which as in the embodiment of FIG. 1B an installation base, including a support base 12 and a conductive layer 4 on its surface, is made. In the embodiment of FIG. 1B too, through-holes 3 used as alignment marks are made in the base. This can be carried out, for example, in the manner shown in FIG. 1A. Unlike the embodiment of FIG. 1A, in the B modification of the example process (FIG. 1B), contact bumps 5 are made on the surface of the conductive film 4. The contact bumps 5 are intended to connect a component installed later to the conductive film 4. In the example process, the contact bumps are made from some metallurgically compatible material, such a gold (Au). The contact bumps can be manufactured using some surfacing process generally known in the circuit-board industry.

The contact bumps 5 can be made in the conductive film 4 is some appropriate stage, for example, before making the through-holes 3 or other alignment marks. In that case, the contact bumps 5 are aligned relative to each other while to the alignment marks, such as through-holes 3, of the alignment-mark making stage are aligned relative to the contact bumps 5. Another alternative is to make the alignment marks first and make the contact bumps 5 after this in the selected positions, with the aid of the alignment marks.

Stage A can also be performed in the same way in embodiments in which a self-supporting conductive layer 4 is used and from which the support layer 12 is thus totally missing.

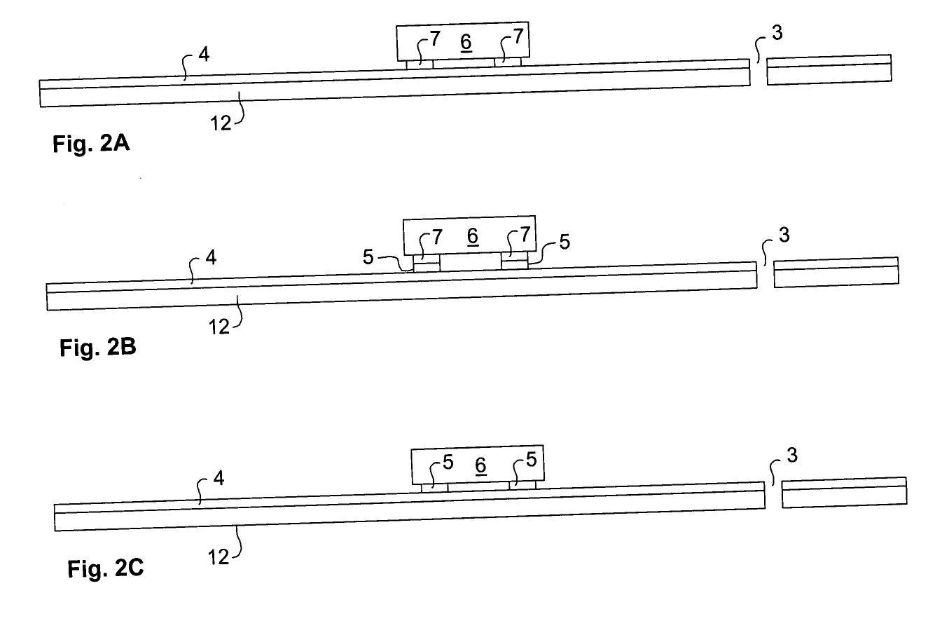

Stage B (FIGS. 2A, 2B, and 2C):

Three modifications of stage B are shown. In the A modification (FIG. 2A), a component 6, which includes contact bumps 7 in the connection zones of the component, is attached to the conductive layer 4. The contact bumps 7 of the component are connected to the conductive layer 4 in such a way that an electrical contact is created between the contact bump 7 and the conductive layer 4. It would be good for the connection to also withstand mechanical stress, so that the connection will not be easily broken in later process stages, or during the operation of the electronic module. The connection is formed using a suitable connection method, for example, the ultrasonic and thermo-compression methods. In the connection stage, the through-holes 3 made for alignment, or other available alignment marks are used to align the component 6.

In the B modification (FIG. 2B) too, a component 6, which includes contact bumps 7 in the connection zones of the component, is connected to the conductive layer 4. The difference to the A modification is that, in the B modification, contact bumps 5 are also formed on top of the conductive layer 4. The contact bumps 7 of the component are then connected to the contact bumps 5 of the installation base. The connection can, as in modification A, be formed using a suitable connection method, for example, the ultrasonic or thermo-compression methods. In the B modification, the component can be aligned, according to the embodiment, using the contact bumps 5, the through-holes 3, or other alignment marks suitable for alignment.

In the C modification of the example process, as in the B modification, an installation base is used, in which contact bumps 5 are made on top of the conductive layer 4. Unlike in the A and B modifications, in the C modification a component 6 is used, the surface of which has flat contact zones, but no actual contact bumps 7, or other corresponding contact protrusions. In the C modification, connection and alignment are carried out as in the B modification, except that the connection is formed between the conductive material of the contact zones and the contact bumps 5 of the installation base. In the following figures, the C modification will be presented in connection with the A modification, as from the point of view of the following process stages, it is of no significance whether the contact bumps are formed of the surface of the component 6 (contact bumps 7), or of the conductive layer 4 (contact bumps 5).

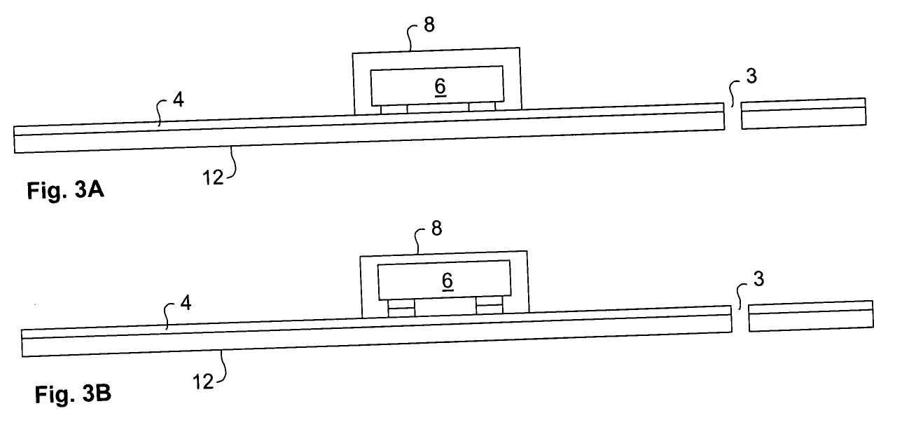

Stage C (FIGS. 3A and 3B):

In stage E, filler 8 is placed under the component 6, by means of which the space remaining between the component 6 and the conductive layer 4 is filled. The filler can also be spread around and on top of the component 6, as is done in the embodiments of FIGS. 3A and 3B. The filler 8 can be, for example, some suitable polymer. For example, epoxy filled with suitable particles can be used as the polymer. The polymer can be spread using, for example, some known vacuum-paste-pressing device suitable for the task. The purpose of the filler 8 is to secure the component 6 mechanically to the conductive layer 4, so that the electronic module will better withstand mechanical stress. In addition, the filler 8 protects the component 6 during later process stages. Protecting the component 6 can be particularly beneficial in embodiments, in which conductive patterns are formed by etching the conductive layer 4 and in which the surface of the component 6 is sensitive to the effect of the etching agent used. Otherwise, the securing of the component is in no way essential and, at least in some embodiments, stage C can be omitted or performed at a later stage in the process.

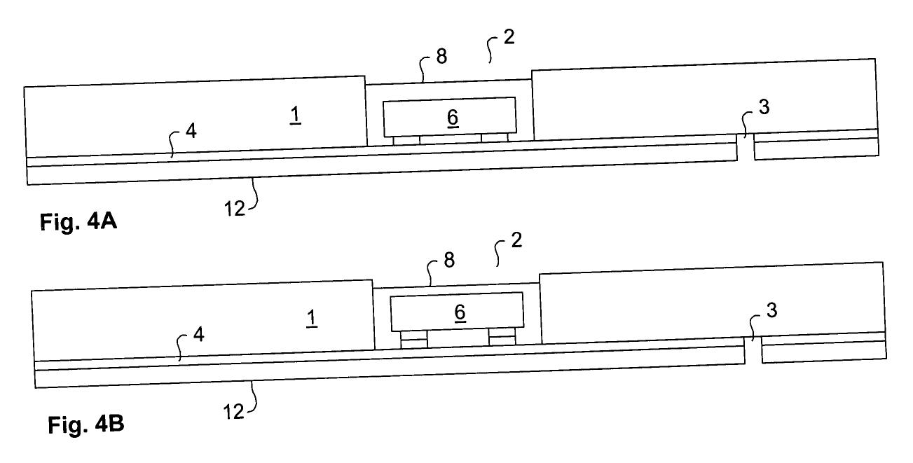

Stage D (FIGS. 4A and 4B):

In stage D, an insulating-material layer 1, in which there are pre-formed cavities 2 or recesses for the components 6 to be attached to the conductive layer 4, is placed on top of the conductive layer 4. The insulating-material layer 1 can be made from a suitable polymer base, in which cavities or recesses according to the size and position of the components 6 are made using some suitable method. The polymer made can be, for example, a pre-preg base known and widely used in the circuit-board industry, which is made from a glass-fibre mat and so-called b-state epoxy.

When manufacturing a very simple electronic module, the insulating-material layer 1 can be attached to the conductive layer 4 in connection with stage D and the process continued with the patterning of the conductive layer 4.

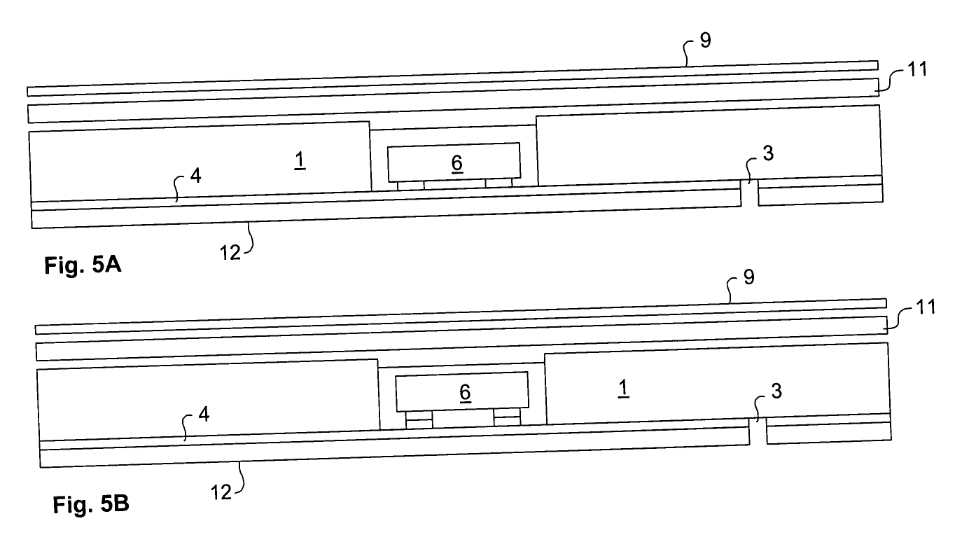

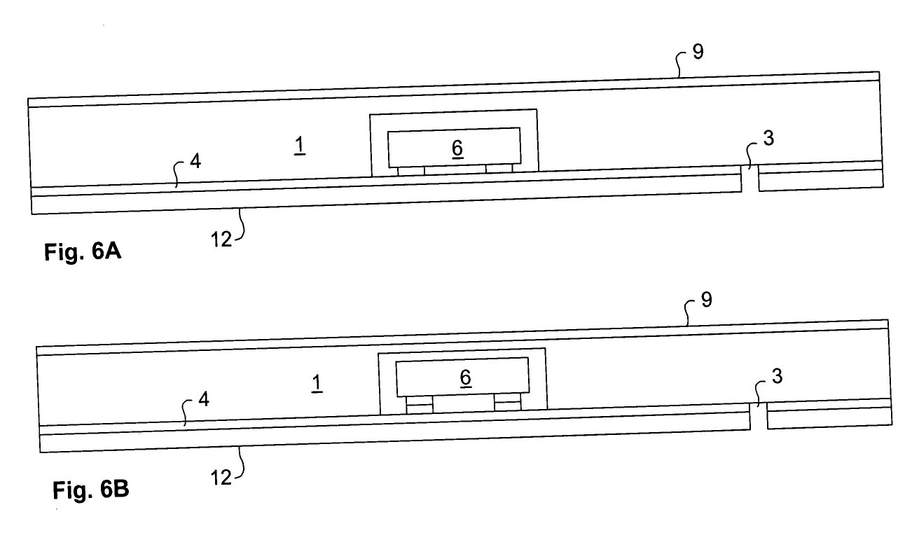

Stage E (FIGS. 5A, 5B, 6A, and 6B):

In stage E, an unpatterned insulating-material layer 11 is placed on top of the insulating-material layer 1 and on top of it a conductive layer 9. Like the insulating-material layer 1, the insulating-material layer 11 can be reinforced with a suitable polymer film, for example, the aforesaid pre-preg base. The conductive layer 9 can, in turn, be, for example, a copper film, or some other film suitable for the purpose. After this, the layers 1, 11, and 9 are pressed with the aid of heat and pressure in such a way that the polymer (in the layers 1 and 11) formed a unified and tight layer between the conductive layer 4 and 9 around the components 6 (see FIGS. 6A and 6B). The use of this procedure makes the second conductive layer 9 quite smooth and even.

When manufacturing simple electronic modules and those including a single conductive-pattern layer 14, stage E can even be totally omitted, or the layers 1 and 11 can be laminated to the construction, without a conductive layer 9.

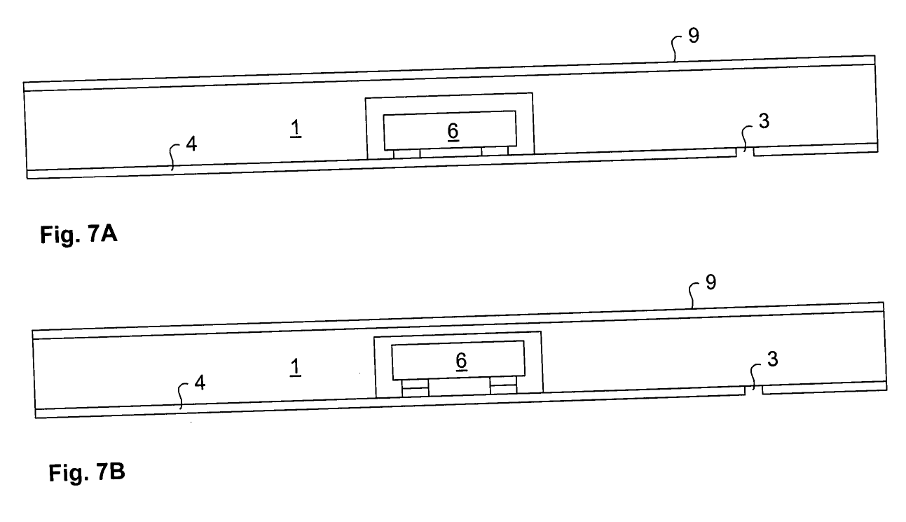

Stage F (FIGS. 7A and 7B):

In stage F, the support base 12 is detached or otherwise removed from the construction.

Removal can take place, for example, mechanically or by etching. Stage F can naturally be omitted from embodiments that do not employ a support base 12.

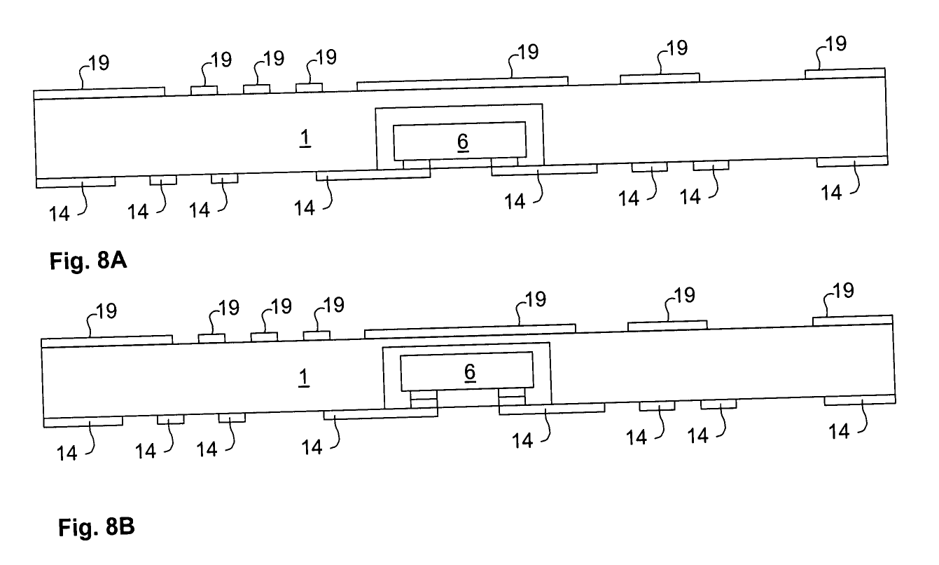

Stage G (FIGS. 8A and 8B):

In stage G, the desired conductive patterns 14 and 19 are formed from the conductive layers 4 and 9 on the surface of the base. If only a single conductive layer 4 is used in the embodiment, the patterns are formed on only one side of the base. It is also possible to proceed in such a way that the conductive patterns are only formed from the conductive layer 4, even though a second layer 9 is also used in the embodiment. In such an embodiment, the unpatterned conducive layer 9 can act, for example, as a mechanically supporting or protective layer of the electronic module, or as a protection against electromagnetic radiation.

The conductive patterns 14 can be made, for instance, by removing the conductive material of the conductive layer 4 from outside of the conductive patterns. The conductive material can be removed, for example, using one of the patterning and etching methods that are widely used and well known in the circuit-board industry. If the conductive layer 4 is made from a special material, the conductive patterns 14 can also formed in such a way that the conductivity of the conductive material 4 is removed from outside of the conductive patterns, for example, with the aid of electromagnetic radiation. When using a conversely reactive material, the material is put into a conductive state in the area of the conductive patterns. Thus, the conductive layer 4 is, in the previous stages of the method, actually the insulating layer, which can be converted to be conductive with the aid of special treatment. The manner of forming the conductive patterns 14 is thus not, as such, essential to the manufacture of the electronic module.

If through-holes 3 are made in the embodiment, the conductive patterns 14 to be made from the conductive layer 4 can be aligned with the aid of the through-holes 3. The conductive patterns 19 made from the conductive layer 9 can also be aligned with the aid of through-holes 3, though the alignment must then be performed from the opposite side of the base.

After stage G, the electronic module includes a component 6, or several components 6 and conductive patterns 14 and 19 (in some embodiments only conductive patterns 14), with the aid of which the component or components 6 can be connected to an external circuit, or to each other. The conditions for manufacturing a functional totality then exist already. The process can thus be designed in such a way that the electronic module is already finished after stage G and FIGS. 8A and 8B show examples of some possible electronic modules that can be manufactured using the example methods. Of course, if it is wished, the process can also continue after stage G, for example, by surfacing the electronic module with a protective substance, or by making additional conductive patterns on the first and/or second surface of the electronic module.

FIG. 9

FIG. 9 shows a multi-layered electronic module, which includes three bases 1 laminated on top of each other, together with their components 6, and a total of six conductive-pattern layers 14 and 19. The bases 1 are attached to each other with the aid of intermediate layers 32. The intermediate layer 32 can be, for example, a pre-preg epoxy layer, which is laminated between the installation bases 1. After this, holes running through the module are drilled in the electronic module, in order to form contacts. The contacts are formed with the aid of a conductive layer 31 grown in the holes. With the aid of the conducts 31 running through the electronic module, the various conductive-pattern layers 14 and 19 of the installation bases 1 can be suitably connected to each other, thus forming a multi-layered functioning totality.

On the basis of the example of FIG. 9, it is clear that the method can also be used to manufacture many different kinds of three-dimensional circuit structures. The method can be used, for example, in such a way that several memory circuits are placed on top of each other, thus forming a package containing several memory circuits, in which the memory circuits are connected to each other to form a single functional totality. Such packages can be termed three-dimensional multichip modules. In modules of this kind, the chips can be selected freely and the contacts between the various chips can be easily manufactured according to the selected circuits.

The sub-modules (bases 1 with their components 6 and conductors 14 and 19) of a multi-layered electronic module can be manufactured, for example, using one of the electronic-module manufacturing methods described above. Some of the sub-modules to be connection to the layered construction can, of course, be quite as easily manufactured using some other method suitable for the purpose.

The examples of FIGS. 1-9 shows some possible processes, with the aid of which our invention can be exploited. Our invention is not, however, restricted to only the processes disclosed above, but instead the invention also encompasses various other processes and their end products, taking into account the full scope of the claims and the interpretation of their equivalences. The invention is also not restricted to only the constructions and method described by the examples, it being instead obvious to one versed in the art that various applications of our invention can be used to manufacture a wide range of different electronic modules and circuit boards, which differ greatly from the examples described above. Thus, the components and wiring of the figures are shown only with the intention of illustrating the manufacturing process. Thus many alterations to and deviations from the processes of the examples shown above can be made, while nevertheless remaining within the basic idea according to the invention. The alterations can relate, for example, to the manufacturing techniques described in the different stages, or to the mutual sequence of the process stages.

With the aid of the method, it is also possible to manufacture component packages for connection to a circuit board. Such packages can also include several components that are connected electrically to each other.

The method can also be used to manufacture total electrical modules. The module can also be a circuit board, to the outer surface of which components can be attached, in the same way as to a conventional circuit board.

1. A method for manufacturing an electronic modules, the method comprising:
taking a metallic conductive layer,
taking a component, which has a contacting surface, which has metallic contact zones,
connecting the component to the first surface of the conductive layer by an ultrasonic or thermo-compression method, in such a way that metallurgical joints and at the same time electrical contacts are formed between the conductive layer and the contact zones of the component,
making, on the first surface of the conductive layer, an insulating-material layer, which surrounds the component connected to the conductive layer, and
making conductive patterns from the conductive layer.

2. A method according to claim 1, in which the metallurgical joints are formed by connecting the contact zones to the conductive layer directly and without interfacing medium.

3. A method according to claim 1, in which the contact zones are metal and in which, prior to the formation of the electrical contact, metal contact bumps are grown on top of the conductive layer, and in which the metallurgical joints are formed via contact bumps by connecting the contact zones metallurgically to the contact bumps.

4. A method according to claim 1, in which the conductive layer is metal and, prior to the formation of the electrical contact, metal contact bumps are grown on top of the contact zones of the component, and in which the metallurgical joints are formed via contact bumps by connecting the contact bumps metallurgically to the conductive layer.

5. A method according to claim 2, in which the metallurgical connection is implemented solderlessly.

6. A method according to claim 1, in which
at least one alignment mark is made on the installation base, for the alignment of a component, and
the component is set in the installation hole, aligned relative to at least one alignment mark.

7. A method according to claim 6, in which at least one alignment mark is a through hole, which penetrates the conductive layer.

8. A method according to claim 7, in which the conductive patterns are aligned relative to the component, with the aid of at least one through hole.

9. A method according to claim 1, in which the space between the component and the conductive layer is filled with a filler, for example, a polymer.

10. A method according to claim 1, in which conductive patterns are made from the conductive layer of the installation base by removing part of the material of the conductive layer, so that the remaining material forms conductive patterns.

11. A method according to claim 1, in which a support layer is attached to the conductive layer, and is removed after the manufacture of the insulating-material layer, but before the manufacture of the conductive patterns.

12. A method according to claim 1, in which the insulating-material layer surrounding the component is manufactured by attaching an insulating-material layer, in which cavities or recesses for a component or components are made, to the conductive layer.

13. A method according to claim 12, in which a second insulating-material layer, which is unified and which covers the component, is attached to the surface of the first insulating-material layer attached to the conductive layer.

14. A method according to claim 1, in which a second conductive-pattern layer is manufactured on the opposite surface of the insulating-material layer.

15. A method according to claim 1, in which more than one component is embedded in the electronic module in a corresponding manner.

16. A method according to claim 15, in which conductive patterns are made from the conductive layer, in such a way that, by means of the conductive patterns, an electrical connection is formed between at least two components.

17. A method according to claim 15, in which the components embedded in the base are connected electrically to each other, in order to form a functioning totality.

18. A method according to claim 1, in which a first module is manufactured along with at least one second module and the manufactured modules are attached to each other one on top of the other, so that the modules are aligned relative to each other.

19. A method according to claim 18, in which holes for feed-throughs are made through the modules that are attached on top of each other and conductors are made in the holes thus created, in order to connect the electronic circuits on each of the moduless to each other to form a functional totality.

20. An electronic module, which includes
an insulating-material layer, which has a first surface and a second surface,
at least one cavity or recess in the insulating-material layer, which opens out onto the first surface,
at least two components inside the at least one cavity or recess, which components include contact zones on that side of the component that faces the first surface of the insulating-material layer, and which components are positioned in such a way that the contact zones are located at a distance from the level of the first surface of the insulating-material layer,
a first conductive-pattern layer, which contains at least one metal and runs on the first surface of the insulating-material layer and extends on top of the at least one cavity or recess in the insulating-material layer at the location of the contact zones of the components,
contact bumps for forming electrical contact between the first conductive pattern layer and the contact zones of the component, which contact bumps contain at least one metal, and
a second conductive-pattern layer, which runs on the second surface of the insulating-material layer and by means of feed-throughs connects to the first conductive-pattern layer to connect the components as a functional entity,
and in which module the contact bumps metallurgically and solderlessly connect to the first conductive-pattern layer substantially at the level of the first surface of the insulating-material layer.

21. An electronic module, which includes
an insulating-material layer, which has a first surface and a second surface,
at least one cavity or recess in the insulating-material layer, which opens out onto the first surface,
at least two components inside the at least one cavity or recess, which components include contact zones substantially at the level of the first surface of the insulating-material layer, the contact zones containing at least one metal,
a first conductive-pattern layer, which contains at least one metal and runs over the first surface of the insulating-material layer and extends on top of the at least one cavity or recess in the insulating-material layer, and
a second conductive-pattern layer, which runs on the second surface of the insulating-material layer and by means of feed-throughs connects to the first conductive-pattern layer to connect the components as a functional entity,
and in which module the first conductive-pattern layer metallurgically and solderlessly connects to the contact bumps of said at least one component substantially at the level of the first surface of the insulating-material layer.

22. An electronic module according to either claim 20, in which the thickness of the component is less than the thickness of the insulating-materia layer in the direction between the first surface and the second surface of the insulating-material layer.

23. An electronic module according to claim 20, in which the cavity or recess contains a filler material between the component and the insulating-material layer, for securing the component to the insulating-material layer.

24. An electronic module according to claim 20, in which the said conductive-pattern layer is essentially flat, so that that surface of the conductive-pattern layer that lies against the insulating-material layer and the cavity or recess in the insulating-material layer for the component, is located entirely at essentially the level of the first surface of the insulating-material layer.

25. An electronic module according to claim 20, in which the cavity or recess extends through the whole insulating-material layer in the direction between the first surface and the second surface of the insulating-material layer.

26. An electronic module according to claim 20, wherein the second conductive layer includes conductive-patterns at the location of the component in the cavity or recess.
